(19) United States
(12) Patent Application Publication
(10) Pub. No.: US 2025/0218889 A1
(43) Pub. Date: Jul. 3, 2025

(54) SEMICONDUCTOR PACKAGES AND MANUFACTURING METHODS THEREOF

(71) Applicant: Samsung Electronics Co., Ltd., Suwon-si (KR)

(72) Inventors: Min Ki Kim, Suwon-si (KR); Jin Kyeong Seol, Suwon-si (KR)

(21) Appl. No.: 18/969,881

(22) Filed: Dec. 5, 2024

(30) Foreign Application Priority Data
Jan. 2, 2024 (KR) 10-2024-0000191

(51) Int. Cl. H01L 23/34; H01L 23/00; H01L 25/065

(52) U.S. Cl. CPC H01L 23/34; H01L 24/08; H01L 24/09; H01L 24/80; H01L 24/95; H01L 25/0657; H01L 2224/08146; H01L 2224/09181; H01L 2224/80203; H01L 2224/80895; H01L 2224/80896; H01L 2224/95; H01L 2225/06541; H01L 2225/06565

(57) ABSTRACT

A semiconductor package includes a buffer die; a first core die on the buffer die; and a first dummy die on the first core die, wherein the buffer die includes: a first substrate including a first surface and a second surface; a first bonding insulating film on the second surface, wherein the first core die includes: a second substrate including a third surface facing the second surface and a fourth surface; and a second bonding insulating film that is in contact with the first bonding insulating film, wherein the first dummy die includes: a third substrate including a fifth surface facing the fourth surface and a sixth surface; a third bonding insulating film on the sixth surface; and a first metal pattern in the third bonding insulating film extending from a first corner region across a central portion of the first dummy die.

### CROSS-REFERENCE TO RELATED APPLICATIONS

This application claims priority under 35 U.S.C. 119 from Korean Patent Application No. 10-2024-0000191 filed on Jan. 2, 2024 in the Korean Intellectual Property Office, the contents of which in its entirety are herein incorporated by reference.

### BACKGROUND OF THE INVENTION

### 1. Technical Field

The present disclosure relates to semiconductor packages and methods for manufacturing the same. More specifically, the present disclosure relates to semiconductor packages and methods for manufacturing the same that improves performance and reliability of a product (e.g., the semiconductor packages) by alleviating a delamination phenomenon between semiconductor dies.

### 2. Description of the Related Art

Semiconductor packages are being developed to efficiently manufacture semiconductor chips with more diverse functions and higher reliability. Furthermore, in order to mount multiple semiconductor chips in the same area, a stacked semiconductor package in which a plurality of such semiconductor chips is stacked has been proposed. In this way, when the plurality of semiconductor chips is stacked, a warpage may occur due to a difference in coefficient of thermal expansion between the materials for forming the semiconductor chips. In particular, when a warpage phenomenon of the semiconductor chips occurs, a delamination phenomenon between the semiconductor chips may occur, which may cause defects in the semiconductor product (e.g., the stacked semiconductor packages). The semiconductor packages may need to to eliminate or minimize failure and degradation of thermal and electrical properties in various environments.

### SUMMARY OF THE INVENTION

Aspects of the present disclosure provide a semiconductor package that may improve performance and reliability of a product by alleviating the delamination phenomenon between semiconductor dies.

Aspects of the present disclosure also provide a method for manufacturing a semiconductor package that may improve performance and reliability of the product by alleviating a delamination phenomenon between the semiconductor dies.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor package comprising: a buffer die; a first core die on the buffer die; and a first dummy die on the first core die, wherein the buffer die includes: a first substrate that includes a first surface and a second surface that are opposite to each other in a first direction; a first bonding insulating film on the second surface of the first substrate; and a first bonding pad that extends in the first bonding insulating film in the first direction, wherein the first core die includes: a second substrate that includes a third surface that faces the second surface of the first substrate and a fourth surface that is opposite to the third surface in the first direction; a second bonding insulating film that is in contact with the first bonding insulating film; and a second bonding pad that extends in the second bonding insulating film in the first direction and is in contact with the first bonding pad, wherein the first dummy die includes: a third substrate that includes a fifth surface that faces the fourth surface of the second substrate and a sixth surface that is opposite to the fifth surface in the first direction; a third bonding insulating film on the sixth surface of the third substrate; and a first metal pattern in the third bonding insulating film, wherein the first metal pattern includes a first pattern that extends from a first corner region of the first dummy die across a central portion of the first dummy die in a plan view, and wherein the first direction is perpendicular to the first surface and/or the second surface of the buffer die.

According to an aspect of the present disclosure, there is provided a semiconductor package comprising: a buffer die; a first core die on the buffer die; and a first dummy die on the first core die, wherein the buffer die includes: a first substrate that includes a first surface and a second surface that are opposite to each other in a first direction; a first bonding insulating film that includes a third surface that faces the second surface of the first substrate and a fourth surface that is opposite to the third surface in the first direction; and a first bonding pad that is exposed from the fourth surface, wherein the first core die includes: a second substrate that includes a fifth surface that faces the second surface of the first substrate and a sixth surface that is opposite to the fifth surface in the first direction; a second bonding insulating film that is in contact with the first bonding insulating film and includes a seventh surface that faces the fourth surface of the first bonding insulating film and an eighth surface that is opposite to the seventh surface in the first direction; and a second bonding pad that is exposed from the seventh surface and is in contact with to the first bonding pad, wherein the first dummy die includes: a third substrate that includes a ninth surface that faces the sixth surface of the second substrate and a tenth surface that is opposite to the ninth surface in the first direction; a third bonding insulating film on the tenth surface of the third substrate; and a first metal pattern in the third bonding insulating film, wherein the first dummy die includes a first edge and a second edge that are opposite to each other in a second direction that intersects the first direction, wherein the first edge extends from a first end to a second end in a third direction that intersects the first direction and the second direction, wherein the second edge extends from a third end to a fourth end in the third direction, wherein the first end and the third end are spaced apart from each other in the second direction, wherein the second end and the fourth end are spaced apart from each other in the second direction, wherein at least a part of the first metal pattern extends from adjacent the first end toward the fourth end in a plan view, wherein the first direction is perpendicular to the first surface and/or the second surface of the buffer die, and wherein the second direction and the third direction are parallel with the first surface and/or the second surface of the buffer die.

According to an aspect of the present disclosure, there is provided a method for manufacturing a semiconductor package, the method comprising: providing a buffer die that includes a first substrate that has a first surface and a second surface opposite to each other in a first direction, a first bonding insulating film on the second surface of the first substrate, and a first bonding pad that extends in the first bonding insulating film in the first direction; providing a core die that includes a second substrate that has a third surface and a fourth surface opposite to each other in the first direction, a second bonding insulating film on the third surface of the second substrate, and a second bonding pad that extends in the second bonding insulating film in the first direction; providing a first dummy die that includes a third substrate that has a fifth surface and a sixth surface opposite to each other in the first direction, a third bonding insulating film on the sixth surface of the third substrate, and a first metal pattern in the third bonding insulating film, wherein the first metal pattern includes a first pattern that extends from a first corner region of the first dummy die across a central portion of the first dummy die in a plan view; stacking the core die and the first dummy die in order on the buffer die; applying a pressure to the core die and the first dummy die on the buffer die to bond the first bonding insulating film and the second bonding insulating film to each other; and applying a heat to the core die and the first dummy die on the buffer die to bond the first bonding pad and the second bonding pad to each other, wherein the first direction is perpendicular to the first surface and/or the second surface of the buffer die.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example diagram for illustrating a semiconductor package according to some embodiments.

FIG. 2 is an example cross-sectional view taken along I-I of FIG. 1.

FIG. 3 is an example cross-sectional view taken along II-II of FIG. 1.

FIG. 4 is an example diagram for explaining a semiconductor package according to some other embodiments.

FIG. 5 is an example cross-sectional view taken along III-III of FIG. 4.

FIG. 6 is an example cross-sectional view taken along VI-VI of FIG. 4.

FIG. 7 is an example diagram for illustrating a semiconductor package according to some embodiments.

FIG. 8 is an example diagram for illustrating a semiconductor package according to some embodiments.

FIG. 9 is an example cross-sectional view for illustrating a semiconductor package according to some embodiments.

FIG. 10 is an example cross-sectional view for illustrating a semiconductor package according to some embodiments.

FIG. 11 is an example cross-sectional view for illustrating a semiconductor package according to some embodiments.

FIG. 12 is a flowchart of a method for manufacturing a semiconductor package according to some embodiments.

FIGS. 13 to 15 are cross-sectional views of intermediate steps for illustrating the method for manufacturing the semiconductor package shown in FIG. 12.

FIG. 16 is a flowchart of a method for manufacturing a dummy die including a metal pattern according to some embodiments.

FIGS. 17 to 22 are cross-sectional views of intermediate steps for illustrating the method for manufacturing the dummy die including the metal pattern shown in FIG. 16.

FIG. 23 is a flowchart of a method for manufacturing a dummy die including a metal pattern according to some embodiments.

FIGS. 24 to 29 are cross-sectional views of intermediate steps for illustrating the method for manufacturing the dummy die including the metal pattern shown in FIG. 23.

### DETAILED DESCRIPTION OF THE INVENTION

Hereinafter, semiconductor packages and methods for manufacturing the same according to some embodiments will be described with reference to the accompanying drawings.

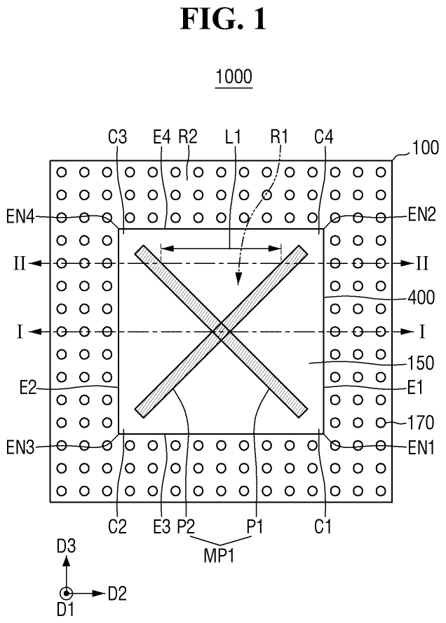

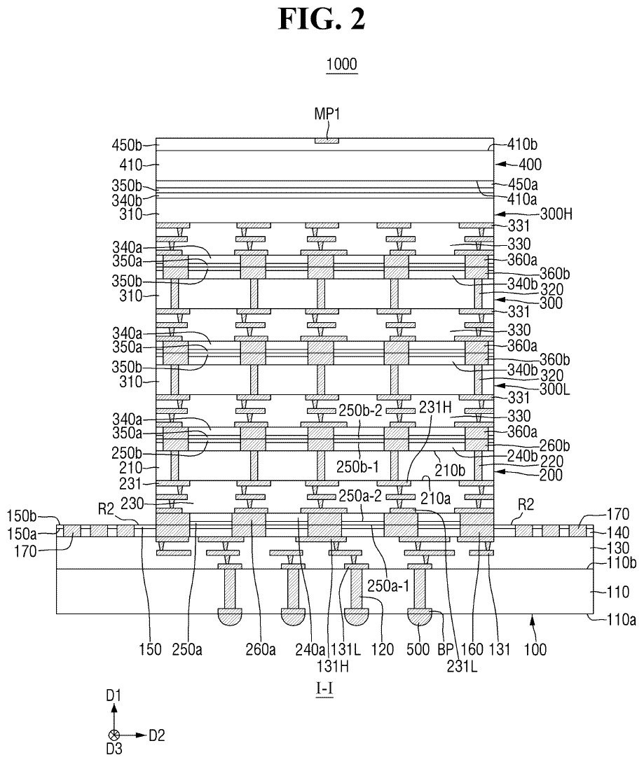

FIG. 1 is an example diagram for illustrating a semiconductor package according to some embodiments. FIG. 2 is an example cross-sectional view taken along I-I of FIG. 1.

Referring to FIGS. 1 and 2, the semiconductor package 1000 may include a buffer die 100, a first core die 200, a plurality of second core dies 300L, 300 and 300H, a dummy die 400, and a connecting terminal 500.

Hereinafter, an upper surface (or an upper part) and a lower surface (or a lower part) may be based on a first direction D1. For example, the first direction D1 may be perpendicular to an upper surface and a lower surface of the buffer die 100. The first direction D1 may be referred to as a vertical direction.

The buffer die 100, the first core die 200, and the second core dies 300L, 300, and 300H may constitute a die structure. Although FIG. 2 shows that three second core dies 300L, 300, and 300H are disposed on the first core die 200, the embodiment is not limited thereto. According to embodiments, the semiconductor package 1000 may include multiple (e.g., 7, 11, or 15) second core dies on (above) the buffer die 100 and the first core die 200. However, for convenience of explanation, the following explanation assumes that the semiconductor package 1000 includes three second core dies 300L, 300, and 300H.

The first core die 200 may be disposed on the buffer die 100, and the second core dies 300L, 300, and 300H may be disposed on the first core die 200. The buffer die 100, the first core die 200, and the second core dies 300L, 300, and 300H may overlap with each other in the first direction D1. As used herein, “an element A overlapping an element B in a direction X” (or similar language) means that there is at least one line that extends in the direction X and intersects both the elements A and B. In some embodiments, the first core die 200 and the second core dies 300L, 300, and 300H may be aligned with each other in the first direction D1.

In some embodiments, the buffer die 100 may not include memory cells. For example, the buffer die 100 may include a serial-parallel conversion circuit, a test logic circuit such as a DFT (design for test), a JTAG (Joint Test Action Group), and a MBIST (memory built in self-test), and a signal interface circuit such as a PHY. For example, the buffer die 100 may be a buffer chip for controlling the first core die 200 and the second core dies 300L, 300, and 300H.

The first core die 200 and the second core dies 300L, 300, and 300H may include a memory cell. For example, the first core die 200 and the second core dies 300L, 300, and 300H may include a volatile memory such as a dynamic random access memory (DRAM) and/or a static random access memory (SRAM) and/or non-volatile memory such as a phase-change random access memory (PAM), a magneto-resistive random access memory (MRAM), a ferroelectric random access memory (FeRAM) and/or a resistive random access memory (RRAM).

In some embodiments, the buffer die 100, the first core die 200, and the second core dies 300L, 300, and 300H may constitute an High Bandwidth Memory (HBM). For example, the buffer die 100 may be a buffer chip for controlling an HBM DRAM, and the first core die 200 and the second core dies 300L, 300, and 300H may be memory cell chips having cells of HBM DRAM controlled by the buffer die 100. In some embodiments, the buffer die 100 may be referred to as a buffer chip, a master chip, or an HBM controller die, and the first core die 200 and the second core dies 300L, 300, and 300H may be referred to as memory chips, slave chips, DRAM dies, or DRAM slices. The buffer die 100, and the first core die 200 and the second core dies 300L, 300, and 300H stacked on the buffer die 100 may be referred to as an HBM DRAM device or an HBM DRAM chip.

In some embodiments, the buffer die 100 may include a physical layer and a direct access region. The physical layer of the buffer die 100 may include interface circuits for communicating with an external host device, and the external host device may be electrically connected to the buffer die 100 through a connecting terminal 500, which will be described below. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device. It will be understood that when an element or layer is referred to as being “connected to”, “coupled to”, “responsive to”, or “on” another element or layer, it may be directly connected to, coupled to, responsive to, or on the other element or layer, or one or more intervening elements or layers may be present. In contrast, when an element is referred to as being “directly coupled,” “directly connected,” or “directly responsive to”, or “directly on,” another element, there are no intervening elements present. In addition, “electrical connection” conceptually includes a physical connection and a physical disconnection.

The first core die 200 and the second core dies 300L, 300, and 300H may receive signals from or transmit signals to the buffer die 100 through the physical layer. Signals and/or data received through the physical layer of the buffer die 100 may be transferred to the first core die 200 and the second core dies 300L, 300, and 300H through the bonding pads 160, 260a, 260b, 360a and 360b. A direct access region may provide an access path that may test the first core die 200 and/or the second core dies 300L, 300, and 300H without going through the buffer die 100. For example, the electrical characteristics of the first core die 200 and/or the second core dies 300L, 300, and 300H may be tested through the access path provided by the direct access region. The direct access region may include conductive means that may communicate directly with an external test device.

In some embodiments, the buffer die 100 may include a substrate 110, a through via 120, an insulating layer 130, a redistribution layer 131, a passivation layer 140, a bonding insulating film 150, and a bonding pad 160. The substrate 110 may be, for example, bulk silicon or silicon-on-insulator (SOI). In some embodiments, the substrate 110 may be a silicon substrate or may include other materials, for example, but not limited to, silicon germanium, silicon germanium on insulator (SGOI), indium antimonide, lead telluride, indium arsenide, indium phosphide, gallium arsenide and/or gallium antimonide.

The substrate 110 may include a surface 110a and a surface 110b that are opposite to each other in the first direction D1. The surface 110a may be opposite to the first core die 200, and the surface 110b may face the first core die 200. The connecting terminal 500 may be disposed on the surface 110a, and the bonding pad 160 and the first core die 200 may be disposed on the surface 110b. For example, the surface 110a of the substrate 110 may be referred to as a lower surface of the substrate 110, and the surface 110b of the substrate 110 may be referred to as an upper surface of the substrate 110.

A bump pad BP may be disposed inside the substrate 110. The bump pad BP may expose from the surface 110a of the first substrate 110. That is, in FIG. 2, a lower (a bottom) surface of the bump pad BP may be disposed on the same plane as (may be coplanar with) the surface 110a. Further, an upper surface of the bump pad BP may face the first core die 200.

The bump pad BP may be used to electrically connect an external device and the first core die 200. The connecting terminal 500 may be disposed below the bump pad BP. For example, the connecting terminal 500 may be on the lower surface of the bump pad BP. Although not shown, the connecting terminal 500 may be electrically connected to the external device, and the external device and the buffer die 100 may be electrically connected through the connecting terminal 500.

The connecting terminal 500 may be formed of a single layer or multiple layers. When the connecting terminal 500 is formed of a single layer, the connecting terminal 500 may include, for example, tin-silver (Sn—Ag) solder or copper (Cu). When the connecting terminal 500 is formed of multiple layers, the connecting terminal 500 may include, for example, copper (Cu) filler and solder. However, the technical idea of the present disclosure is not limited thereto, and the number, spacing, placement form, and the like of the connecting terminals 500 are not limited to those shown in the drawings, and of course, may vary depending on the design.

The through via 120 may be disposed inside the substrate 110. The through via 120 may extend in the first direction D1 (on the bump pad BP) on the surface 110a of the substrate 110. The through via 120 may play the role of electrically connecting the redistribution layer 131 and the bump pad BP. That is, the redistribution layer 131 and the bump pad BP may be electrically connected through the through via 120. The through via 120 may include, for example, but not limited to, a metal material copper (Cu) and/or aluminum (Al).

An insulating layer 130 may be disposed on the surface 110b of the substrate 110. The insulating layer 130 may include (e.g., may be made of), for example, photoimageable dielectric (PID). As an example, the insulating layer 130 may include a photosensitive polymer. The photosensitive polymer may include (e.g., may be formed of), for example, photosensitive polyimide, polybenzoxazole, phenolic polymer, and/or benzocyclobutene-based polymer. In some embodiments, the insulating layer 130 may include (e.g., may be formed of) a silicon oxide film, a silicon nitride film and/or a silicon oxynitride film.

The redistribution layer 131 may be disposed inside the insulating layer 130. The redistribution layer 131 may be made up of the multiple layers. For example, the redistribution layer 131 may include a wiring portion extending in a second direction D2, and a via portion connected to the wiring portion and extending in the first direction D1. At this time, the first direction D1 and the second direction D2 may intersect each other. The second direction D2 may be parallel with the upper surface and/or the lower surface of the buffer die 100. Furthermore, the redistribution layer 131 may include a first sub-layer and a second sub-layer, and a via portion of the first sub-layer may be connected to a wiring portion of the second sub-layer. At this time, the level of the wiring portion of the first sub-layer may be different from the level of the wiring portion of the second sub-layer. However, the technical idea of the present disclosure is not limited thereto. The (vertical) level may be a relative location (e.g., distance) from a common plane (e.g., the upper surface or the lower surface of the buffer die 100) in a vertical direction (e.g., the first direction D1). For example, a farther distance in the first direction D1 from the lower surface of the buffer die 100 may be a higher level.

A redistribution layer 131L disposed at the lowest level among the redistribution layers 131 may be connected (e.g., electrically connected) to the through via 120. A redistribution layer 131H disposed at the highest level among the redistribution layers 131 may be connected (e.g., electrically connected) to the bonding pad 160. The redistribution layer 131 may include, for example, but not limited to, copper (Cu), aluminum (Al), silver (Ag), tin (Sn), gold (Au), nickel (Ni), lead (Pb), titanium (Ti) and/or alloys thereof.

A passivation layer 140 may be disposed on the insulating layer 130. The passivation layer 140 may include an insulating material. For example, the passivation layer 140 may be formed of a silicon oxide film. The passivation layer 140 may overlap in the first direction D1 with (e.g., cover) the upper surface of the insulating layer 130 and protect the upper surface of the insulating layer 130.

A bonding insulating film 150 may be disposed on the passivation layer 140. The bonding insulating film 150 may extend long along the upper surface of the passivation layer 140. The bonding insulating film 150 may include a surface 150a and a surface 150b. The surface 150a and the surface 150b may be opposite to each other in the first direction D1. The surface 150a may face the surface 110b of the substrate 110. For example, the surface 150a of the bonding insulating film 150 may be a lower surface of the bonding insulating film 150. The surface 150b of the bonding insulating film 150 may include a first region R1 and a second region R2. The surface 150b may be the upper surface of the bonding insulating film 150, the first region R1 may be a region corresponding to a central portion of the upper surface of the bonding insulating film 150, and the second region R2 may be a region extending around (e.g., surrounding) the first region R1 (in a plan view). That is, the second region R2 may be a region corresponding to the edge of the upper surface (e.g., the surface 150b) of the bonding insulating film 150.

A plurality of connecting pads 170 may be disposed in the second region R2. The connecting pads 170 may be pads which connect (e.g., electrically connect) another semiconductor chip or semiconductor die stacked on the buffer die 100 and the buffer die 100, in addition to the first core die 200 and the second core dies 300L, 300, and 300H. For example, the first core die 200, and the second core dies 300L, 300, and 300H may be disposed in the first region R1.

The bonding insulating film 150 may include a different insulating material from the passivation layer 140. For example, the bonding insulating film 150 may include (e.g., may be formed of) silicon carbonitride film (SiCN). The bonding insulating film 150 may be bonded to a bonding insulating film 250a of the first core die 200, which will be described below. Herein, when element A and element B are bonded, element A and element B may be in contact with each other.

A bonding pad 160 may be disposed in the passivation layer 140. The bonding pad 160 may extend in (e.g., penetrate) the bonding insulating film 150 and the passivation layer 140 in the first direction D1. In some embodiments, a lower surface of the bonding pad 160 may be coplanar with a lower surface of the passivation layer 140, and the upper surface of the bonding pad 160 may be coplanar with the upper surface of the bonding insulating film 150. The bonding pad 160 may be disposed in the first region R1 of the surface 150b. The bonding pad 160 may be at least partially exposed from the surface 150b (e.g., the upper surface) of the bonding insulating film 150. The bonding pads 160 may be used to electrically connect the buffer die 100 and the first core die 200. That is, the bonding pad 160 may be bonded to a bonding pad 260a of the first core die 200, which will be described below.

The first core die 200 may include a substrate 210, a through via 220, an insulating layer 230, a redistribution layer 231, a passivation layer 240a, a bonding insulating film 250a, a bonding pad 260a, a passivation layer 240b, a bonding insulating film 250b, and a bonding pad 260b.

The substrate 210 may be, for example, bulk silicon or silicon-on-insulator (SOI). In some embodiments, the substrate 210 may be a silicon substrate or may include other materials, for example, but not limited to, silicon germanium, silicon germanium on insulator (SGOI), indium antimonide, lead telluride, indium arsenide, indium phosphide, gallium arsenide and/or gallium antimonide.

The substrate 210 may include a surface 210a and a surface 210b that are opposite to each other in the first direction D1. The surface 210a may face the surface 110b of the substrate 110. That is, the surface 210a of the second substrate 210 may face the buffer die 100, and the surface 210b of the substrate 210 may be opposite to the buffer die 100. For example, the surface 210a of the second substrate 210 may be a lower surface of the second substrate 210, and the surface 210b of the second substrate 210 may be an upper surface of the second substrate 210.

A through via 220 may be disposed inside the substrate 210. The through via 220 may extend in the first direction D1 inside the substrate 210. The through via 220 may play a role of electrically connecting the redistribution layer 231 and the bonding pad 260b. That is, the redistribution layer 231 and the bonding pad 260b may be electrically connected through the through via 220. The through via 220 may include, for example, but not limited to, a metal material such as copper (Cu) and/or aluminum (Al).

The insulating layer 230 may be disposed on the surface 210a of the substrate 210. The insulating layer 230 may include (e.g., may be made of) photoimageable dielectric (PID). As an example, the insulating layer 230 may include a photosensitive polymer. The photosensitive polymer may include (e.g., may be formed of), for example, photosensitive polyimide, polybenzoxazole, phenolic polymer, and/or benzocyclobutene-based polymer. In some embodiments, the insulating layer 230 may include (e.g., may be formed of) a silicon oxide film, a silicon nitride film, and/or a silicon oxynitride film.

The redistribution layer 231 may be disposed inside the insulating layer 230. The redistribution layer 231 may be made up of the multiple layers. For example, the redistribution layer 231 may include a wiring portion extending in the second direction D2, and a via portion connected to the wiring portion and extending in the first direction D1. In addition, the redistribution layer 231 may include a first sub-layer and a second sub-layer, and a via portion of the first sub-layer may be connected (e.g., electrically connected) to a wiring portion of the second sub-layer. At this time, the level of the wiring portion of the first sub-layer may be different from the level of the wiring portion of the second sub-layer. However, the technical idea of the present disclosure is not limited thereto.

A redistribution layer 231H disposed at the highest level among the redistribution layers 231 may be connected (e.g., electrically connected) to the through via 220. A redistribution layer 231L disposed at the lowest level among the redistribution layers 231 may be connected (e.g., electrically connected) to the bonding pad 260a. The redistribution layer 231 may include, for example, but not limited to, copper (Cu), aluminum (Al), silver (Ag), tin (Sn), gold (Au), nickel (Ni), lead (Pb), titanium (Ti) and/or alloys thereof.

The passivation layer 240a may be disposed on the lower surface of the insulating layer 230. The passivation layer 240a may include an insulating material. For example, the passivation layer 240a may include (e.g., may be formed of) a silicon oxide film. The passivation layer 240a may overlap in the first direction D1 with (e.g., cover) the lower surface of the insulating layer 230 and protect the lower surface of the insulating layer 230.

A bonding insulating film 250a may be disposed on the lower surface of the passivation layer 240a. The bonding insulating film 250a may extend long along the lower surface of the passivation layer 240a. The bonding insulating film 250a may include a surface 250a-1 and a surface 250a-2. The surface 250a-1 and the surface 250a-2 may be opposite to each other in the first direction D1. The surface 250a-1 may face the surface 150b of the bonding insulating film 150. For example, the surface 250a-1 may be a lower surface of the bonding insulating film 250a. The bonding insulating film 250a may include a different insulating material from the passivation layer 240a. For example, the bonding insulating film 250a may include (e.g., may be formed of) silicon carbonitride film (SiCN).

The bonding pad 260a may be disposed in the passivation layer 240a. The bonding pad 260a may extend in (e.g., penetrate) the bonding insulating film 250a and the passivation layer 240a in the first direction D1. That is, the upper surface of the bonding pad 260a may be coplanar with the upper surface of the passivation layer 240a, and the lower surface of the bonding pad 260a may be coplanar with the lower surface of the bonding insulating film 250a. The bonding pad 260a may be at least partially exposed from the surface 250a-1 (e.g., the lower surface) of the bonding insulating film 250a. The bonding pad 260a may be used to electrically connect the buffer die 100 and the first core die 200. That is, as the bonding pad 260a is bonded to the bonding pad 160, the buffer die 100 and the first core die 200 may be electrically connected. For example, the bonding pad 260a may include (e.g., may be formed of), but not limited to, copper (Cu).

The passivation layer 240b may be disposed on the surface 210b (e.g., the upper surface) of the substrate 210. The passivation layer 240b may include an insulating material. For example, the passivation layer 240b may include (e.g., may be formed of) a silicon oxide film. The passivation layer 240b may overlap in the first direction D1 (e.g., cover) and protect the surface 210b of the substrate 210.

The bonding insulating film 250b may be disposed on the upper surface of the passivation layer 240b. The bonding insulating film 250b may extend long along the upper surface of the passivation layer 240b. The bonding insulating film 250b may include a surface 250b-1 and a surface 250b-2. The surface 250b-1 and the surface 250b-2 may be opposite to each other in the first direction D1. The surface 250b-1 may face the surface 210b of the substrate 210. For example, the surface 250b-1 of the bonding insulating film 250b may be a lower surface of the bonding insulating film 250b, and the surface 250b-2 of the bonding insulating film 250b may be an upper surface of the bonding insulating film 250b. The bonding insulating film 250b may include a different insulating material from the passivation layer 240b. For example, the bonding insulating film 250b may include (may be formed of) a silicon carbonitride film (SiCN).

The bonding pad 260b may be disposed in the passivation layer 240b. The bonding pad 260b may extend in (e.g., penetrate) the bonding insulating film 250b and the passivation layer 240b in the first direction D1. That is, the upper surface of the bonding pad 260b may be coplanar with the upper surface of the bonding insulating film 250b, and the lower surface of the bonding pad 260b may be coplanar with the lower surface of the passivation layer 240b. The bonding pad 260b may be at least partially exposed from the surface 250b-2 (e.g., the upper surface) of the bonding insulating film 250b. The bonding pad 260b may be used to electrically connect the first core die 200 and the second core die 300L disposed lowest among the second core dies 300L, 300, and 300H. That is, as the bonding pad 260b is bonded to the bonding pad 360a of the second core die 300L disposed lowest among the second core dies 300L, 300, and 300H, which will be described later, the first core die 200 and the second core die 300L may be electrically connected. For example, the bonding pad 260b may include (e.g., may be formed of), but not limited to, copper (Cu).

The plurality of second core dies 300L, 300, and 300H may include the same or substantially similar structure. For example, each of the plurality of second core dies 300L, 300, and 300H may include a substrate 310, a through via 320, an insulating layer 330, a redistribution layer 331, a passivation layer 340a, a bonding insulating film 350a, a bonding pad 360a, a passivation layer 340b, a bonding insulating film 350b, and a bonding pad 360b. However, the second core die 300H disposed uppermost among the plurality of second core dies 300L, 300, and 300H may not include the through vias 320 and the bonding pads 360b.

Explanation (e.g., explanation of the structure) of the substrate 310, the through via 320, the insulating layer 330, the redistribution layer 331, the passivation layer 340a, the bonding insulating film 350a, the bonding pad 360a, the passivation layer 340b, the bonding insulating film 350b, and the bonding pad 360b included in each of the plurality of second core dies 300L, 300, and 300H may be identical or substantially similar to explanation (e.g., explanation of the structure) of the substrate 210, the through via 220, the insulating layer 230, the redistribution layer 231, the passivation layer 240a, the bonding insulating film 250a, the bonding pad 260a, the passivation layer 240b, the bonding insulating film 250b, and the bonding pad 260b of the first core die 200, and therefore will not be provided below.

In this way, in the embodiments of the present disclosure, the bonding insulating films of the buffer die 100 and the first core die 200, the first core die 200 and the second core die 300L, and the plurality of second core dies 300L, 300, and 300H are bonded to each other. As the bonding pads (e.g., bonding pads 160, 260a, 260b, 360a, and 360b) are bonded to each other, the semiconductor package 1000 may be manufactured in a hybrid copper bonding manner using a thermal compression process.

The dummy die 400 may include a substrate 410, a bonding insulating film 450a, a bonding insulating film 450b, and a metal pattern MP1.

The substrate 410 may be, for example, bulk silicon or silicon-on-insulator (SOI). In some embodiments, the substrate 410 may be a silicon substrate or may include other materials, for example, but not limited to, silicon germanium, silicon germanium on insulator (SGOI), indium antimonide, lead telluride, indium arsenide, indium phosphide, gallium arsenide and/or gallium antimonide.

The substrate 410 may include a surface 410a and a surface 410b that are opposite to each other in the first direction D1. The surface 410a may face the second core die 300H disposed uppermost among the second core dies 300L, 300, and 300H, and the surface 410b may be opposite to the second core die 300H. For example, the surface 410a of the substrate 410 may be a lower surface of the substrate 410, and the surface 410b of the substrate 410 may be an upper surface of the substrate 410.

The bonding insulating film 450a may be disposed on the surface 410a of the substrate 410, and the bonding insulating film 450b may be disposed on the surface 410b of the substrate 410. The bonding insulating film 450a may extend long along the lower surface of the substrate 410, and the bonding insulating film 450b may extend long along the upper surface of the substrate 410. The bonding insulating film 450a and the bonding insulating film 450b may each include an insulating material, for example, silicon nitride (SiCN). The bonding insulating film 450a and the bonding insulating film 450b may each be formed of a single layer or multiple layers.

The bonding insulating film 450a of the dummy die 400 and the bonding insulating film 350b of the second core die 300H disposed uppermost among the plurality of second core dies 300L, 300, and 300H may be bonded to each other. For example, when heat and pressure are applied to the first core die 200, the plurality of second core dies 300L, 300, and 300H, and the dummy die 400 stacked in order on the buffer die 100 to manufacture a semiconductor package (e.g., the semiconductor package 1000) in the hybrid copper bonding manner, heat and pressure may also be applied between the bonding insulating film 350b and the bonding insulating film 450a. Accordingly, the two bonding insulating films facing each other may be thermally expanded, and may be subjected to diffusion bonding to form an integration through diffusion of atoms included in each bonding insulating film and being in contact with each other.

The dummy die 400 may include a first edge E1 and a second edge E2 that are opposite to each other in the second direction D2. The first edge E1 and the second edge E2 may each extend in a third direction D3. At this time, the third direction D3 may intersect the first direction D1 and the second direction D2. The third direction D3 may be parallel with the upper surface and/or the lower surface of the buffer ide 100. The first edge E1 may extend from a first end EN1 to a second end EN2 along the third direction D3. The second edge E2 may extend from a third end EN3 to a fourth end EN4 along the third direction D3. The first end EN1 and the third end EN3 may be disposed side by side with each other in the second direction D2. For example, the first end EN1 and the third end EN3 may be spaced apart from each other in the second direction D2. The second end EN2 and the fourth end EN4 may be disposed side by side in the second direction D2. For example, the second end EN2 and the fourth end EN4 may be spaced apart from each other in the second direction D2.

The dummy die 400 may include a third edge E3 and a fourth edge E4 that are opposite to each other in the third direction D3. The third edge E3 and the fourth edge E4 may each extend in the second direction D2. The third edge E3 may extend from the third end EN3 to the first end EN1 along the second direction D2. The fourth edge E4 may extend from the fourth end EN4 to the second end EN2 along the second direction D2.

A corner region may be formed at regions where each edge of the dummy die 400 join each other. For example, a first corner region C1 may be formed at a region where the first edge E1 and the third edge E3 join, and a second corner region C2 may be formed at a region where the second edge E2 and the third edge E3 join. Further, a third corner region C3 may be formed at a region where the second edge E2 and the fourth edge E4 join, and a fourth corner region C4 may be formed at a region where the first edge E1 and the fourth edge E4 join. A corner region may include (may be adjacent) an end. For example, the first corner region C1 may include (may be adjacent) the first end EN1, the second corner region C2 may include (may be adjacent) the third end EN3, the third corner region C3 may include (may be adjacent) the fourth end EN4, and the fourth corner region C4 may include (may be adjacent) the second end EN2, in a plan view.

The dummy die 400 may include a metal pattern MP1 inside the bonding insulating film 450b. The metal pattern MP1 may include a first pattern P1. In some embodiments, the dummy die 400 may be a semiconductor die in which a metal pattern MP1 is formed on dummy substrate made only of a semiconductor material such as silicon through a photolithography process. For example, the dummy die 400 may be a semiconductor die in which a metal pattern MP1 is formed in a portion of a bare wafer (e.g., the substrate 410) through the photolithography process.

The first pattern P1 may include a pattern extending from the first corner region C1 of the dummy die 400 across the central portion of the dummy die 400 in a plan view. For example, the first pattern P1 may extend from the first corner region C1 across the central portion of the dummy die 400 to the third corner region C3 in a plan view.

The metal pattern MP1 may further include a second pattern P2. The second pattern P2 may include a pattern extending from the second corner region C2 of the dummy die 400 across the central portion of the dummy die 400 in a plan view. For example, the second pattern P2 may extend from the second corner region C2 across the central portion of the dummy die 400 to the fourth corner region C4 in a plan view. Therefore, the metal pattern MP1 may include a shape in which the first pattern P1 and the second pattern P2 intersect each other at the central portion of the dummy die 400 in a plan view.

In some embodiments, at least a part of the metal pattern MP1 may extend from the first end EN1 to the fourth end EN4 of the dummy die 400 in a plan view. In some embodiments, at least a part of the metal pattern MP1 may extend from adjacent the first end EN1 toward the fourth end EN4 of the dummy die 400 in a plan view. Furthermore, at least a part of the metal pattern MP1 may extend from the second end EN2 to the third end EN3 of the dummy die 400 in a plan view. In some embodiments, at least a part of the metal pattern MP1 may extend from adjacent the second end EN2 toward the third end EN3 of the dummy die 400 in a plan view.

The metal pattern MP1 may include, for example, copper (Cu), aluminum (Al), and titanium (Ti). The coefficient of thermal expansion of the material forming the metal pattern MP1 may be higher than the coefficient of thermal expansion of the material forming the substrate 410. For example, the coefficient of thermal expansion of metal included in the metal pattern MP1 may be higher than that of silicon forming the substrate 410. Therefore, when bonding the semiconductor dies by applying heat to the first core die 200, the second core dies 300L, 300, and 300H, and the dummy die 400 on the buffer die 100 by an annealing process, the metal pattern MP1 having a high coefficient of thermal (a higher coefficient of thermal than that of the substrate 410) may press the first to fourth corner regions C1 to C4 of the dummy die 400 downward (that is, in an opposite direction to the first direction D1), while expanding. As a result, it is possible to alleviate a phenomenon in which the corner region of the first core die 200 rises upward (i.e., in the first direction D1), and the delamination occurs between the buffer die 100 and the first core die 200.

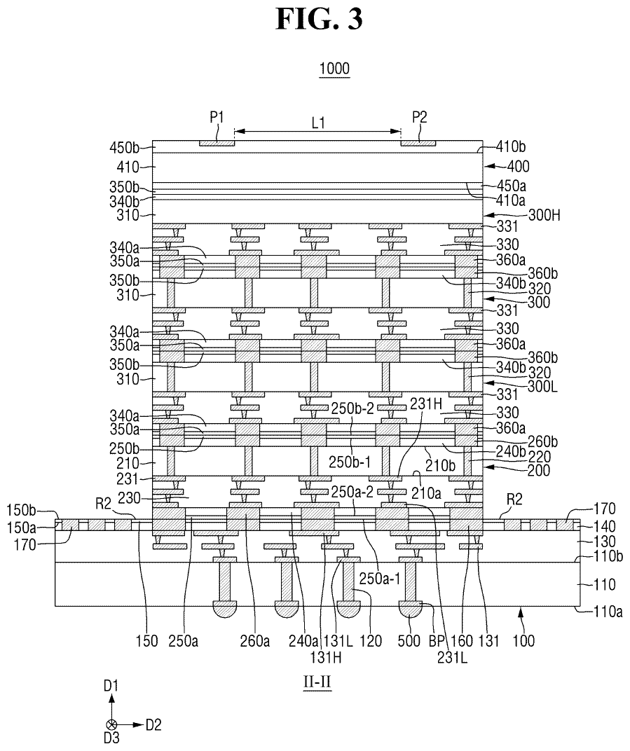

FIG. 3 is an example cross-sectional view taken along II-II of FIG. 1.

The shape of the metal pattern MP1 appearing in the cross section of the semiconductor package 1000 may vary depending on which part of the semiconductor package 1000 of FIG. 1 is cut along. For example, referring to FIGS. 1 and 2, when the metal pattern MP1 is cut along the central portion of the dummy die 400 in a plan view, that is, along the line I-I of FIG. 1, as shown in FIG. 2, the shape of the metal pattern MP1 appearing on the cross section of the semiconductor package 1000 may appear in the form in which the first pattern P1 and the second pattern P2 intersect. Next, referring to FIGS. 1 and 3, when cutting along II-II of FIG. 1, as shown in FIG. 3, the shape of the metal pattern MP1 appearing on the cross section of the semiconductor package 1000 may appear in the form in which the first pattern P1 and the second pattern P2 are spaced apart by a length L1 in the second direction D2.

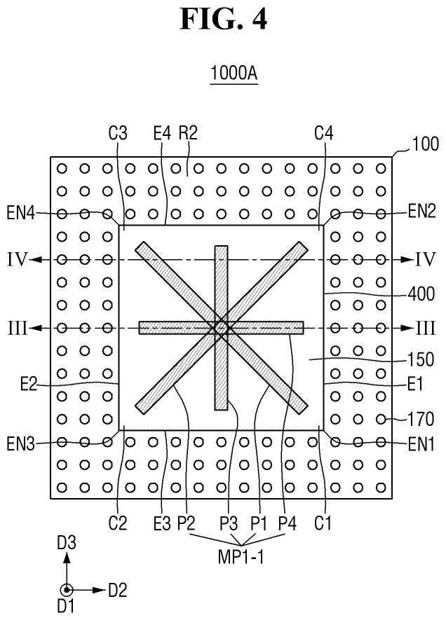

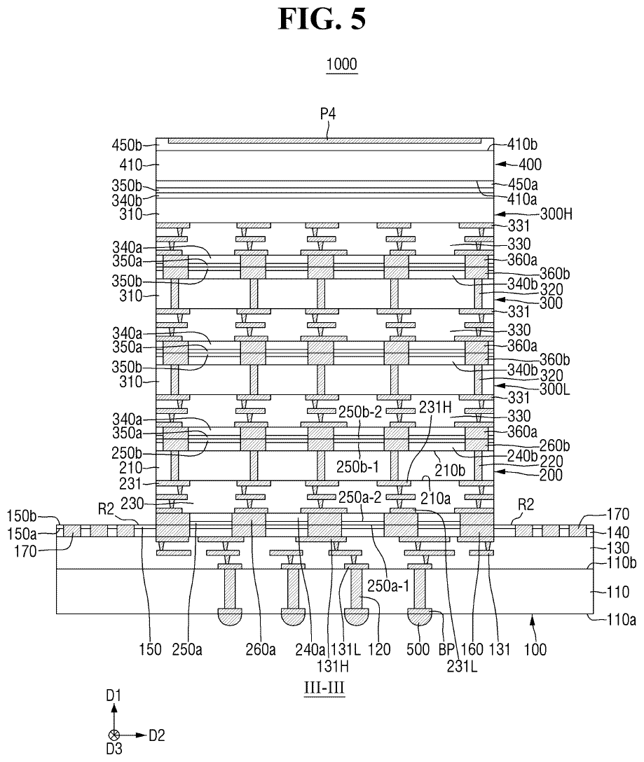

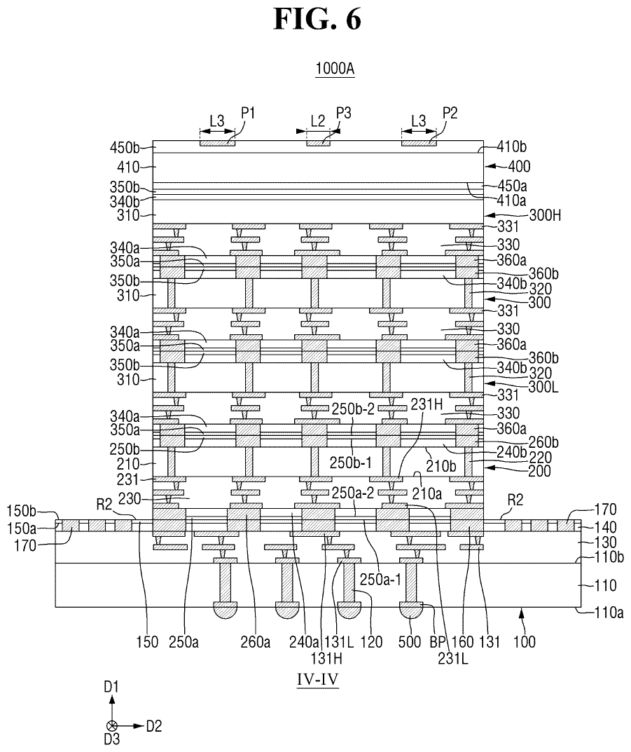

FIG. 4 is an example diagram for explaining a semiconductor package according to some other embodiments. FIG. 5 is an example cross-sectional view taken along III-III of FIG. 4. FIG. 6 is an example cross-sectional view taken along IV-IV of FIG. 4. Hereinafter, repeated explanations of those of the previous embodiment may be omitted, and the explanation will focus on the differences.

First, referring to FIGS. 4 and 5, unlike the embodiment described with reference to FIGS. 1 to 3, a metal pattern MP1-1 of the dummy die 400 in the semiconductor package 1000A may further include a third pattern P3 and a fourth pattern P4. The third pattern P3 may extend between the third edge E3 of the dummy die 400 and the fourth edge E4 of the dummy die 400 across the central portion of the die 400 in a plan view. For example, the third pattern P3 may extend from the third edge E3 of the dummy die 400 to the fourth edge E4 of the dummy die 400 across the central portion of the dummy die 400 in a plan view. The fourth pattern P4 may extend between the first edge E1 of the dummy die 400 and the second edge E2 of the dummy die 400 across the central portion of the dummy die 400 in a plan view. For example, the fourth pattern P4 may extend from the first edge E1 of the dummy die 400 to the second edge E2 of the dummy die 400 across the central portion of the dummy die 400 in a plan view. In this way, by forming the third pattern P3 and the fourth pattern P4, which have a higher coefficient of thermal expansion than the material (for example, silicon) in (e.g., constituting) the substrate 410 of the dummy die 400, in the subsequent annealing process of manufacturing the semiconductor package 1000A, the third pattern P3 and the fourth pattern P4 (along with the first pattern P1 and the second pattern P2) may press the upper surface of the dummy die 400 (radially) downward, while expanding. Accordingly, it is possible to alleviate the phenomenon in which delamination occurs between the buffer die 100 and the first core die 200 to which the semiconductor dies forming the semiconductor package 1000A are bonded in the hybrid copper bonding manner.

Next, referring to FIG. 6, when the semiconductor package 1000A is cut along IV-IV of FIG. 4, the shape of the metal pattern MP1-1 appearing on the cross section of the semiconductor package 1000A may be a shape in which the first pattern P1, the third pattern P3, and the second pattern P2 are disposed in order in the second direction D2. At this time, a length L3 of the first pattern P1 in the second direction D2 may be identical to a length L3 of the second pattern P2 in the second direction D2. Further, the length L2 of the third pattern P3 in the second direction D2 may be shorter than the length L3 of the first pattern P1 in the second direction D2 and the length L3 of the second pattern P2 in the second direction D2.

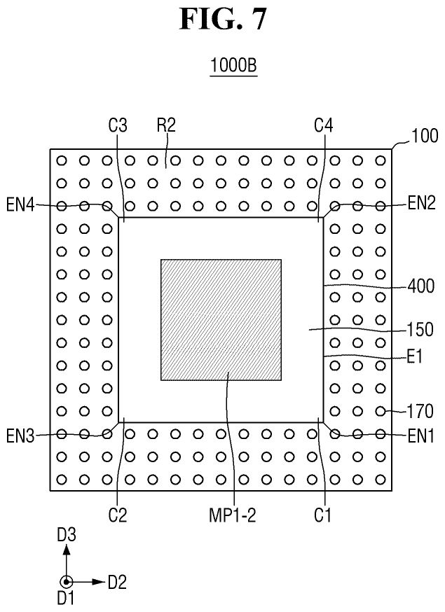

FIG. 7 is an example diagram for illustrating a semiconductor package according to some embodiments.

Referring to FIG. 7, a metal pattern MP1-2 formed in the bonding insulating film 450bof the dummy die 400 in the semiconductor package 1000B may be formed to overlap in the first direction D1 (e.g., cover) the entire regions corresponding to the central portion of the dummy die 400. For example, the metal pattern MP1-2 may be a quadrangle shape located in a central region of the bonding insulating film 450b in a plan view. Accordingly, the edge region in which the metal pattern MP1-2 is not formed on the upper surface of the bonding insulating film 450b may be exposed by the metal pattern MP1-2.

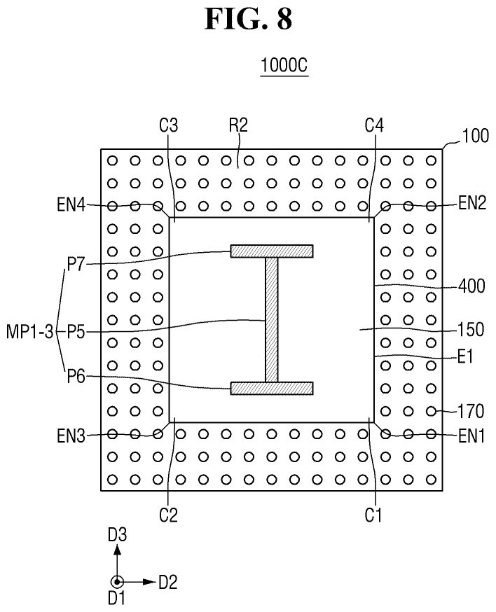

FIG. 8 is an example diagram for illustrating a semiconductor package according to some embodiments.

Referring to FIG. 8, a metal pattern MP1-3 formed in the bonding insulating film 450b of the dummy die 400 in the semiconductor package 1000C may include a pattern P5 extending in the third direction D3 across the central portion of the dummy die 400 in a plan view, a pattern P6 connected to one end of the fifth pattern P5 and extending in the second direction D2 in a plan view, and a pattern P7 connected to the other end of the fifth pattern P5 and extending in the second direction D2 in a plan view.

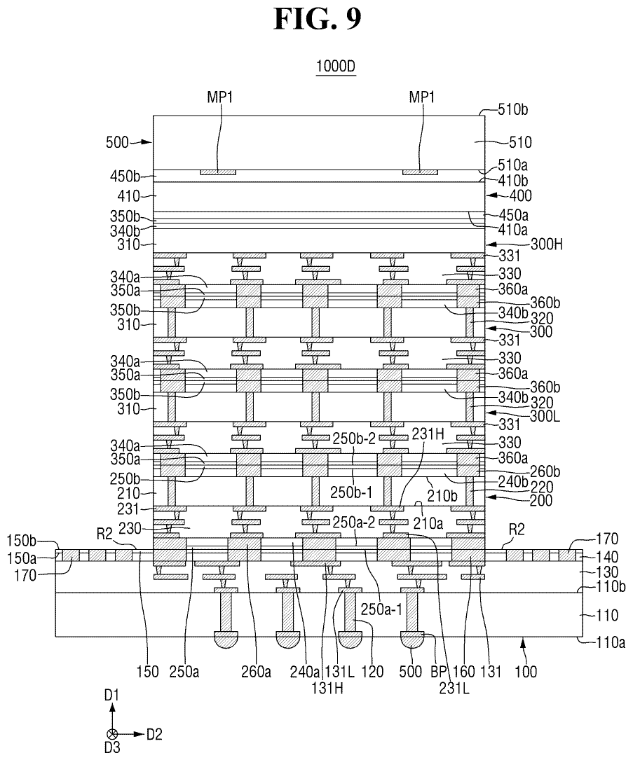

FIG. 9 is an example cross-sectional view for illustrating a semiconductor package according to some embodiments.

Referring to FIG. 9, a semiconductor package 1000D may further include a dummy die 500. The dummy die 500 may include a substrate 510. The substrate 510 may be, for example, bulk silicon or silicon-on-insulator (SOI). In some embodiments, the substrate 510 may be a silicon substrate or may include other material, for example, but not limited to, silicon germanium, silicon germanium on insulator (SGOI), indium antimonide, lead telluride, indium arsenide, indium phosphide, gallium arsenide and/or gallium antimonide.

The substrate 510 may include a surface 510a and a surface 510b that are opposite to each other in the first direction D1. The surface 510a may face the surface 410b of the substrate 410, and the surface 510b may be opposite to the dummy die 400. For example, the surface 510a of the substrate 510 may be a lower surface of the substrate 510, and the surface 510b of the substrate 510 may be an upper surface of the substrate 510.

The dummy die 500 may be dummy substrate which is made only of a semiconductor material such as silicon, that is, has no pattern through a photolithography process. For example, the dummy die 500 may be a part of a bare wafer.

The dummy die 500 may be additionally stacked on the dummy die 400 in a state in which hybrid copper bonding is performed between the buffer die 100, the first core die 200, the plurality of second core dies 300L, 300, and 300H, and the dummy die 400 by a thermal compression process. Accordingly, the dummy die 500 may protect the metal pattern MP1 from exposure to the outside.

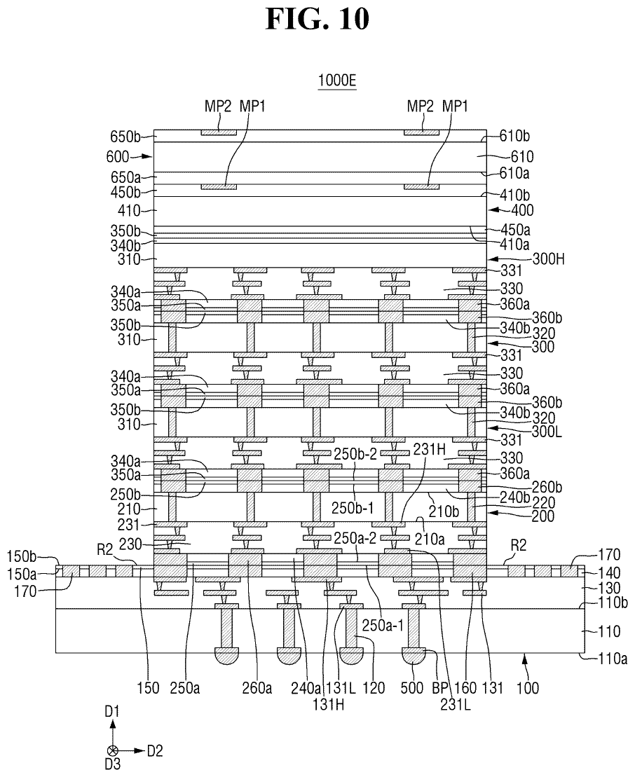

FIG. 10 is an example cross-sectional view for illustrating a semiconductor package according to some embodiments.

Referring to FIG. 10, a semiconductor package 1000E may further include a dummy die 600. The dummy die 600 may include a substrate 610, a bonding insulating film 650a, a bonding insulating film 650b, and a metal pattern MP2.

The substrate 610 may be, for example, bulk silicon or silicon-on-insulator (SOI). In some embodiments, the substrate 610 may be a silicon substrate or may include other materials, for example, but not limited to, silicon germanium, silicon germanium on insulator (SGOI), indium antimonide, lead telluride, indium arsenide, indium phosphide, gallium arsenide and/or gallium antimonide.

The substrate 610 may include a surface 610a and a surface 610b that are opposite to each other in the first direction D1. The surface 610a may face the surface 410b of the substrate 410, and the surface 610b may be opposite to the dummy die 400. For example, the surface 610a of the substrate 610 may be a lower surface of the substrate 610, and the surface 610b of the substrate 610 may be an upper surface of the substrate 610.

The bonding insulating film 650a may be disposed on the surface 610a of the substrate 610, and the bonding insulating film 650b may be disposed on the surface 610b of the substrate 610. The bonding insulating film 650a may extend long along the lower surface of the substrate 610, and the bonding insulating film 650b may extend long along the upper surface of the substrate 610. The bonding insulating film 650a and the bonding insulating film 650b may each include an insulating material, for example, silicon nitride (SiCN). The bonding insulating film 650a and the bonding insulating film 650b may each be formed of a single layer or multiple layers.

The dummy die 600 may include a metal pattern MP2 inside the bonding insulating film 650b. In FIG. 10, the metal pattern MP1 and the metal pattern MP2 are shown similarly (or identical) to the embodiment regarding the metal pattern MP1 described with reference to FIG. 3, but the embodiment is not limited thereto. That is, the metal pattern MP1 and the metal pattern MP2 of the semiconductor package 1000E may be implemented as any one of the embodiments related to the metal pattern MP1 described with reference to FIGS. 1 to 8 (e.g., the metal patterns MP1, MP1-1, MP1-2, and MP1-3), respectively. In some embodiments, the form of the metal pattern MP1 may be different from the form of the metal pattern MP2.

When a thermal compression process is performed to manufacture the semiconductor package 1000E, heat and pressure may be applied to the dummy die 600 stacked on the dummy die 400. At this time, heat and pressure may also be applied between the bonding insulating film 450b of the dummy die 400 and the bonding insulating film 650a of the dummy die 600. Accordingly, the two bonding insulating films facing each other may be thermally expanded, and may be subjected to diffusion bonding to form integration through diffusion of atoms which are included in each bonding insulating film, and are in contact with each other.

Although the semiconductor package 1000E is shown to include two dummy dies 400 and 600 in FIG. 10, the number of dummy dies stacked on the plurality of second core dies 300L, 300, and 300H may be greater than two. In this way, since two or more dummy dies, which is formed with a metal pattern including a metal material having a higher coefficient of thermal expansion than the material for forming the substrate, are stacked on top of the core dies, and the semiconductor dies are bonded in a hybrid copper bonding manner, it is possible to further alleviate the phenomenon in which a delamination occurs between the buffer die 100 and the first core die 200.

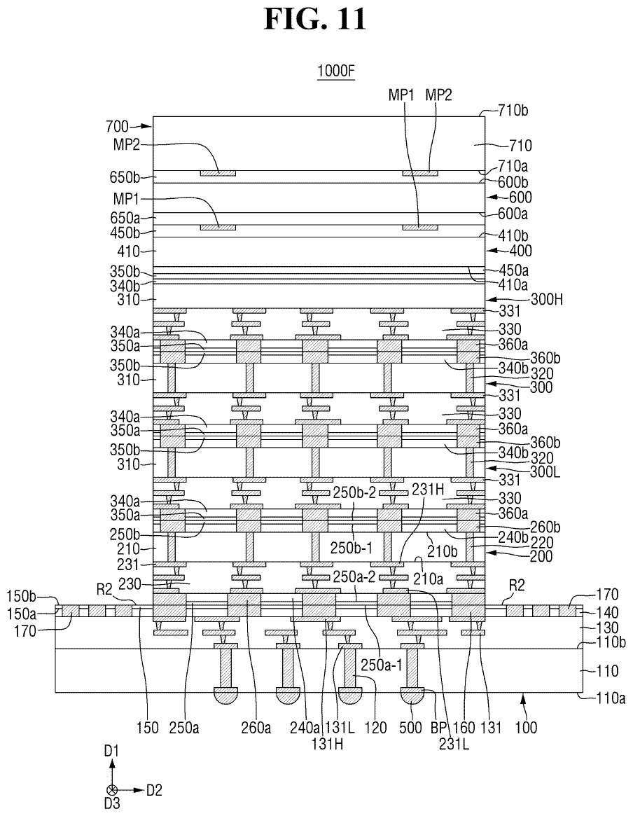

FIG. 11 is an example cross-sectional view for illustrating a semiconductor package according to some embodiments.

Referring to FIG. 11, a semiconductor package 1000F may further include a dummy die 700. The dummy die 700 may include a substrate 710. The explanation of the substrate 710 is the same (or substantially the same) as that of the substrate 510 of FIG. 9, and therefore, will not be provided below.

The dummy die 700 may be dummy substrate which is made only of a semiconductor material such as silicon, that is, has no pattern formed through a photolithography process. For example, the dummy die 700 may be a part of a bare wafer.

The dummy die 700 may be additionally stacked on the dummy die 600, in a state in which hybrid copper bonding is formed between the buffer die 100, the first core die 200, the plurality of second core dies 300L, 300, and 300H, the dummy die 400, and the dummy die 600 by the thermal compression process. Accordingly, the dummy die 700 may protect the metal pattern MP2 from exposure to the outside.

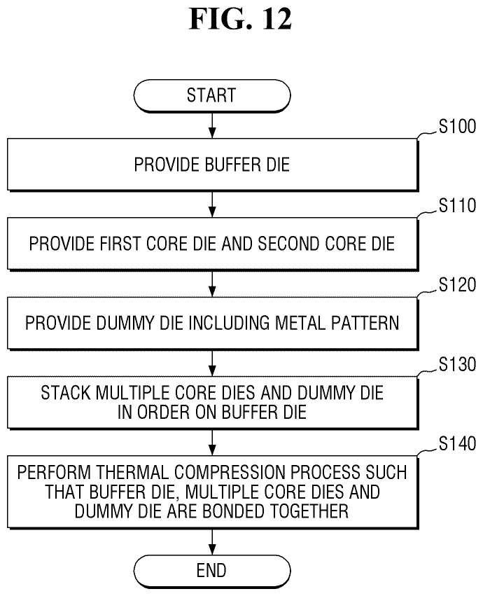

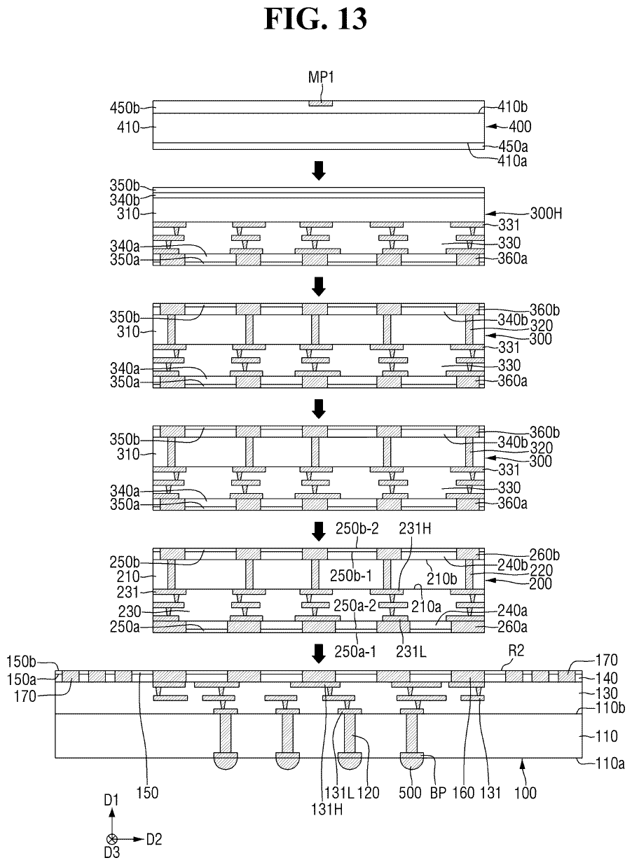

FIG. 12 is a flowchart of a method for manufacturing a semiconductor package according to some embodiments. FIGS. 13 to 15 are cross-sectional views of intermediate steps for illustrating the method for manufacturing the semiconductor package shown in FIG. 12. Hereinafter, the method for manufacturing the semiconductor package according to some embodiments will be described with reference to FIGS. 12 to 15.

First, referring to FIGS. 12 and 13, the buffer die 100, the first core die 200, and the second core dies 300L, 300, and 300H may be provided (S100, S110). Furthermore, the dummy die 400 including the metal pattern MP1 may be provided (S120). Subsequently, the first core die 200, the second core dies 300L, 300, and 300H, and the dummy die 400 may be stacked in this order on the buffer die 100 (S130).

Next, referring to FIGS. 12 to 14, a thermal compression process may be performed so that the buffer die 100, the first core die 200, the second core dies 300L, 300, and 300H, and the dummy die 400 are bonded to each other (S140). According to the embodiments, after a compression process may first be performed between the semiconductor dies, an annealing process for applying heat may be performed. Furthermore, before performing the compression process, oxygen plasma treatment may be performed on the surface of each bonding insulating film.

Hereinafter, a hybrid copper bonding process between the semiconductor dies will be described, using bonding between the buffer die 100 and the first core die 200 as an example. However, it goes without saying that the following description is also equally applicable to the bonding between the first core die 200 and the second core die 300L disposed lowest among the plurality of second core dies 300L, 300, and 300H, and the bonding between the plurality of second core dies 300L, 300, and 300H.

First, the oxygen plasma treatment may be performed on the surface of the bonding insulating film 150 and the surface of the bonding insulating film 250a to form OH on the surface of each bonding insulating film. In this way, a work of performing the oxygen plasma treatment on the surfaces of the bonding insulating film 150 and the bonding insulating film 250a is a surface activation reaction performed so that the bonding insulating films are better bonded to each other in the subsequent compression process. However, the embodiments are not limited thereto, and the surface of the bonding insulating film may be treated with other substances other than oxygen for activation reaction, and in some embodiments, the bonding insulating film may be bonded immediately through the thermal compression process without surface treatment.

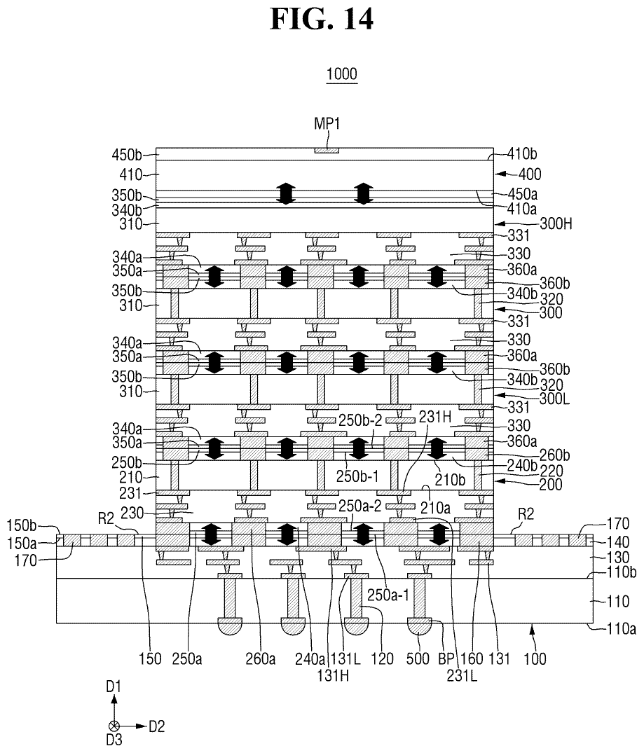

Thereafter, referring to FIG. 14, the bonding insulating film 150 and the bonding insulating film 250a may be bonded to each other through a compression process. For example, when each of the bonding insulating films before the compression process is subjected to oxygen plasma treatment, the bonding insulating films may be bonded to each other by the following reaction formula 1 below.

OH+OH→O+H₂O [Reaction formula 1]

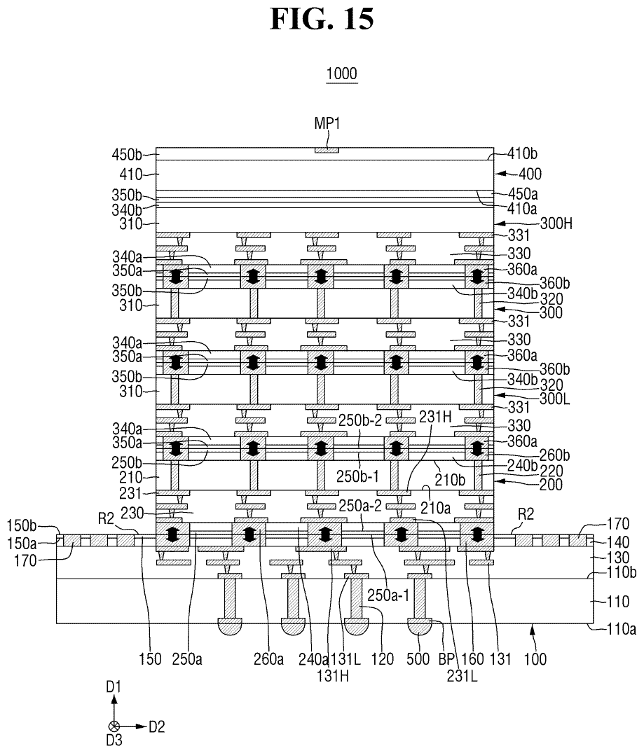

Next, referring to FIG. 15, while the materials forming the bonding pad 160 and the bonding pad 260a, for example, the copper (Cu) contained in the bonding pad 160 and the copper (Cu) contained in the winding pad 260a are being diffused through an annealing process of applying heat to the semiconductor die, the bonding pads may be bonded to each other.

In this way, the bonding insulating film 450a of the dummy die 400 and the bonding insulating film 350b of the second core die 300H disposed uppermost among the plurality of second core dies 300L, 300, and 300H may be bonded to each other through the thermal compression process. Further, at the time of the annealing process, the metal pattern MP1 applies pressure to the portion (for example, the corner region of the first core die 200) in which the first core die 200 is easily delaminated from the buffer die 100, while expanding, thereby alleviating a delamination phenomenon between the buffer die 100 and the first core die 200.

Further, in the thermal compression process for manufacturing the semiconductor package 1000 in this way, after stacking the first core die 200, the second core dies 300L, 300, and 300H, and the dummy dies 400 including the metal pattern MP1 on the buffer die 100, by applying pressure and heat at once, the semiconductor dies may be bonded. Accordingly, the effect of preventing the delamination phenomenon between the first core die 200 and the buffer die 100 while the metal pattern MP1 expands due to heat may be further enhanced.

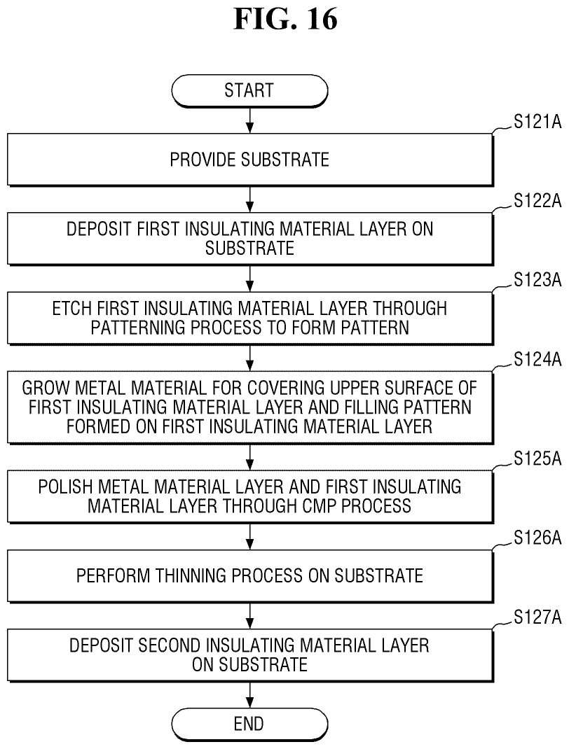

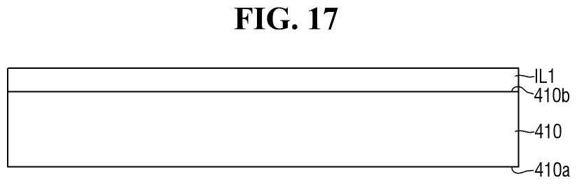

FIG. 16 is a flowchart of a method for manufacturing a dummy die including a metal pattern according to some embodiments. FIGS. 17 to 22 are cross-sectional views of intermediate steps for illustrating the method for manufacturing the dummy die including the metal pattern shown in FIG. 16. Hereinafter, a method for manufacturing the dummy die 400 including the metal pattern MP1 according to some embodiments will be described with reference to FIGS. 16 to 22. It is a matter of course that the following description of the method for manufacturing dummy die 400 including the metal pattern MP1 may be similarly (or identically) applied to the method for manufacturing the dummy die 600 including the metal pattern MP2 of FIG. 10.

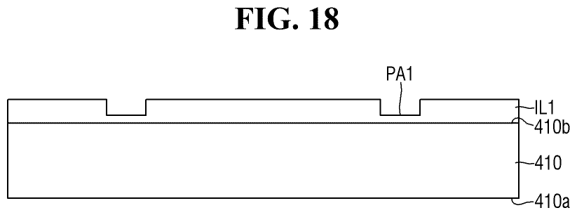

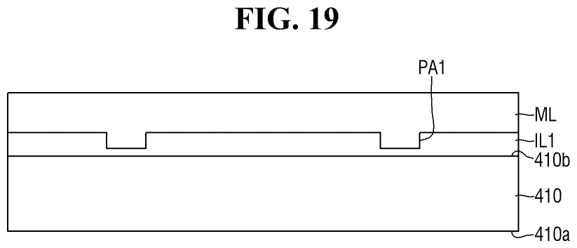

First, referring to FIGS. 16 and 17, a substrate 410 may be provided and an insulating material layer IL1 (a first insulating material layer IL1) may be deposited on the surface 410b(e.g., the upper surface) of the substrate 410 (S121A, S122A). The insulating material layer IL1 may correspond to the bonding insulating film 450b shown in FIG. 2 or the like. Next, referring to FIGS. 16 and 18, the insulating material layer IL1 may be etched through a patterning process to form a pattern PA1 (S123A). The pattern PA1 may include, for example, a shape which recesses from the upper surface of the insulating material layer IL1. Next, referring to FIGS. 16 and 19, the upper surface of the insulating material layer IL1 may be overlapped in the first direction D1 (e.g., covered) by the vapor deposition and electroplating process, and the metal material layer ML which fills the pattern PA1 formed in the insulating material layer IL1 may be grown (S124A). For example., the the metal material layer ML may be on the insulating material layer IL1. At this time, the metal material layer ML may include, for example, a metal material such as copper (Cu), aluminum (Al), and/or titanium (Ti). However, the material included in the metal material layer ML is not limited thereto, and the metal material layer ML may include a material having a higher coefficient of thermal expansion than the material included in the substrate 410.

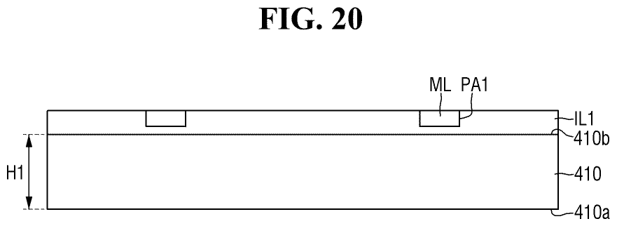

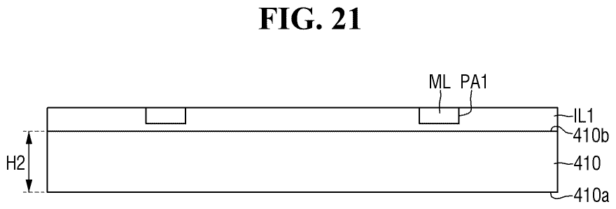

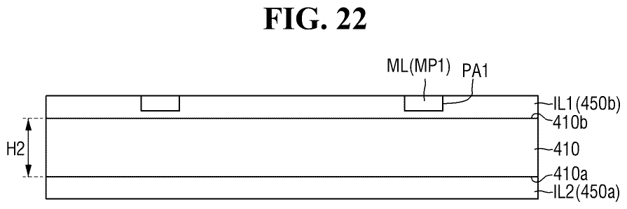

Next, referring to FIGS. 16 and 20, the metal material layer ML and the insulating material layer IL1 may be (at least partially) polished through a CMP (Chemical Mechanical Polishing) process (S125A). Next, referring to FIGS. 16 and 21, a thinning process may be performed on the surface 410a (e.g., the lower surface) of the substrate 410 (S126A). A height H2 of the substrate 410 in the first direction D1 after the thinning process may be shorter than a height H1 of the substrate 410 in the first direction D1 before the thinning process. Thereafter, referring to FIGS. 16 and 22, the insulating material layer IL2 (e.g., the second insulating material layer IL2) may be deposited on the surface 410a (e.g., the lower surface) of the substrate 410 on which the thinning process has been completed (S127A). At this time, the insulating material layer IL2 may correspond to the bonding insulating film 450a of the dummy die 400 shown in FIG. 2 or the like.

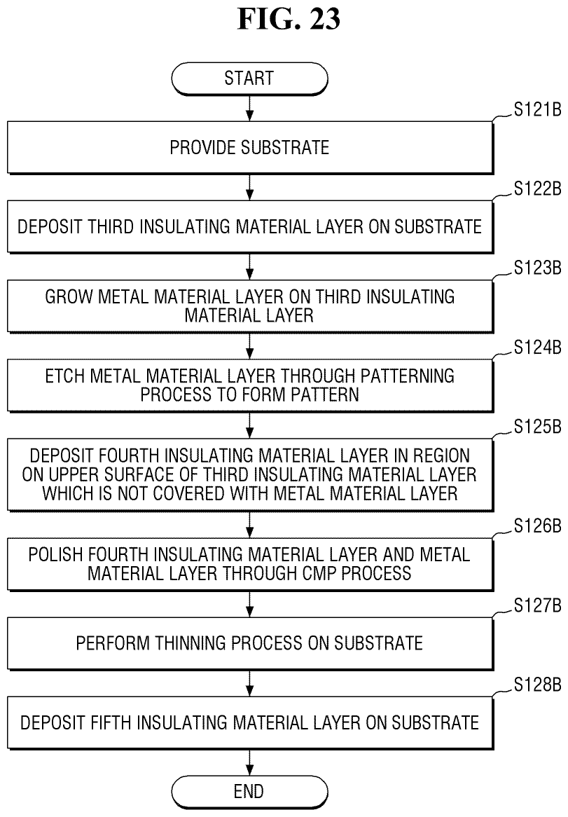

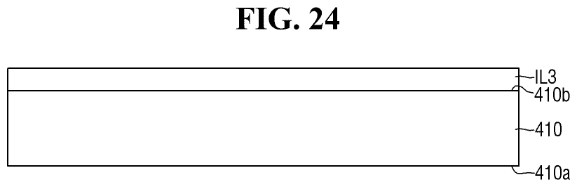

FIG. 23 is a flowchart of a method for manufacturing a dummy die including a metal pattern according to some embodiments. FIGS. 24 to 29 are cross-sectional views of intermediate steps for illustrating the method for manufacturing the dummy die including the metal pattern shown in FIG. 23. Hereinafter, the method for manufacturing the dummy die 400 including the metal pattern MP1 according to some other embodiments will be described with reference to FIGS. 23 to 29. It is a matter of course that the following explanation of the method for manufacturing the dummy die 400 including the metal pattern MP1 may be similarly (or identically) applied to the method for manufacturing the dummy die 600 including the metal pattern MP2 of FIG. 10.

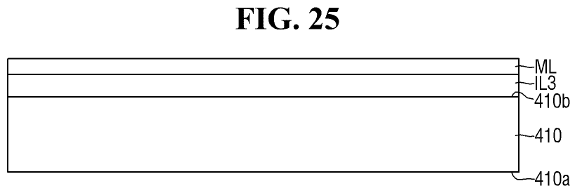

First, referring to FIGS. 23 and 24, a substrate 410 may be provided, and an insulating material layer IL3 (a third insulating material layer IL3) may be deposited on the surface 410b (the upper surface) of the substrate 410 (S121B, S122B). The insulating material layer IL3 may correspond to the bonding insulating film 450b shown in FIG. 2 or the like. Next, referring to FIGS. 23 and 25, a metal material layer ML may be grown on the insulating material layer IL3 through the electroplating process (S123B). At this time, the metal material layer ML may include, for example, a metal material such as copper (Cu), aluminum (Al), and/or titanium (Ti). However, the material included in the metal material layer ML is not limited thereto, and the metal material layer ML may include a material having a higher coefficient of thermal expansion than the material included in the substrate 410.

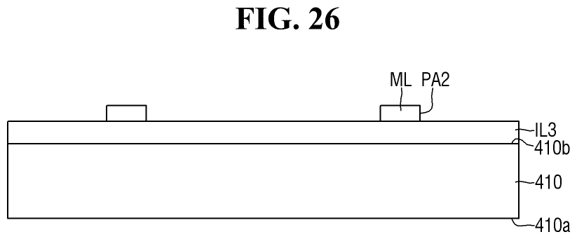

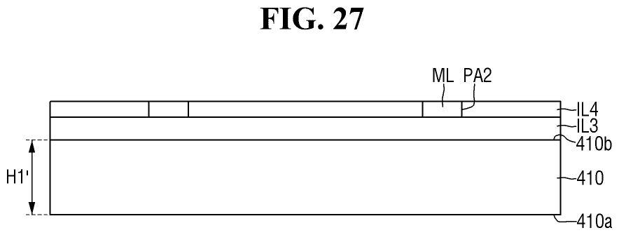

Next, referring to FIGS. 23 and 26, the metal material layer ML may be (at least partially) etched through the patterning process to form a pattern PA2 (S124B). The pattern PA2 may include a shape protruding outward from the upper surface of the insulating material layer IL3. Next, referring to FIGS. 23 and 27, an insulating material layer IL4 (a fourth insulating material layer IL4) may be deposited on the insulating material layer IL3, and the insulating material layer IL4 and the metal material layer ML may be (at least partially) polished through a CMP process (S125B, S126B). At this time, the insulating material layer IL4 may be deposited to overlap in the first direction D1 (e.g., cover) the region of the upper surface of the insulating material layer IL3 that is not overlapped in the first direction D1 (e.g., covered) with the metal material layer ML, and to overlap in the second direction D2 and/or the third direction D3 (e.g., cover) the side surface of the metal material layer ML. An upper surface of the metal material layer ML may be exposed. The insulating material layer IL4 thus formed may correspond to the bonding insulating film 450b shown in FIG. 2 or the like. That is, the insulating material layer IL3 and the insulating material layer IL4 are multi-layers, and may constitute the bonding insulating film 450b.

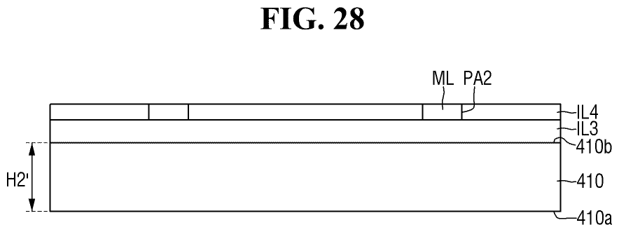

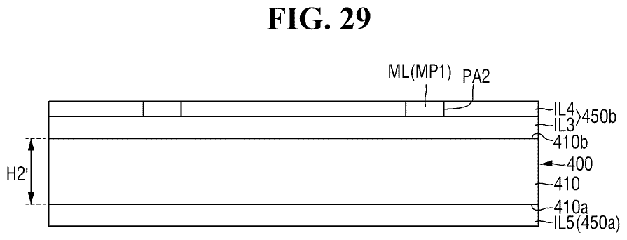

Next, referring to FIGS. 23 and 28, the thinning process may be performed on the surface 410a (e.g., the lower surface) of the substrate 410 (S127B). A height L2′ of the substrate 410 in the first direction D1 after the thinning process may be shorter than a height H1' of the substrate 410 in the first direction D1 before the thinning process. Thereafter, referring to FIGS. 23 and 29, an insulating material layer IL5 (a fifth insulating material layer IL5) may be deposited on the surface 410a of the substrate 410 on which the thinning process has been completed (S128B). At this time, the insulating material layer IL5 may correspond to the bonding insulating film 450a shown in FIG. 2 or the like.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor package comprising:
a buffer die;
a first core die on the buffer die; and
a first dummy die on the first core die,
wherein the buffer die includes:
a first substrate that includes a first surface and a second surface that are opposite to each other in a first direction;
a first bonding insulating film on the second surface of the first substrate; and
a first bonding pad that extends in the first bonding insulating film in the first direction,
wherein the first core die includes:
a second substrate that includes a third surface that faces the second surface of the first substrate and a fourth surface that is opposite to the third surface in the first direction;
a second bonding insulating film that is in contact with the first bonding insulating film; and
a second bonding pad that extends in the second bonding insulating film in the first direction and is in contact with the first bonding pad,
wherein the first dummy die includes:
a third substrate that includes a fifth surface that faces the fourth surface of the second substrate and a sixth surface that is opposite to the fifth surface in the first direction;
a third bonding insulating film on the sixth surface of the third substrate; and
a first metal pattern in the third bonding insulating film,
wherein the first metal pattern includes a first pattern that extends from a first corner region of the first dummy die across a central portion of the first dummy die in a plan view, and
wherein the first direction is perpendicular to the first surface and/or the second surface of the buffer die.

2. The semiconductor package of claim 1,
wherein the first metal pattern further includes a second pattern that extends from a second corner region of the first dummy die across the central portion of the first dummy die in the plan view,
wherein the first corner region and the second corner region are spaced apart from each other in a second direction that intersects the first direction, and
wherein the second direction is parallel with the first surface and/or the second surface of the buffer die.

3. The semiconductor package of claim 1,
wherein the first dummy die includes a first edge and a second edge that face each other in a second direction that intersects the first direction,
wherein the first edge and the second edge each extend in a third direction that intersects each of the first direction and the second direction,
wherein the first metal pattern further includes a second pattern that extends between the first edge and the second edge across the central portion of the first dummy die in the plan view, and
wherein the second direction and the third direction are parallel with the first surface and/or the second surface of the buffer die.

4. The semiconductor package of claim 3,
wherein the first dummy die further includes a third edge and a fourth edge that face each other in the third direction,
wherein the third edge and the fourth edge each extend in the second direction, and
wherein the first metal pattern further includes a third pattern that extends between the third edge and the fourth edge across the central portion of the first dummy die in the plan view.

5. The semiconductor package of claim 1, further comprising:
a second dummy die on the first dummy die,
wherein the second dummy die includes:
a fourth substrate that includes a seventh surface that faces the sixth surface of the third substrate and an eighth surface that is opposite to the seventh surface in the first direction; and
a fourth bonding insulating film on the seventh surface of the fourth substrate,
wherein the fourth bonding insulating film is in contact with the third bonding insulating film.

6. The semiconductor package of claim 5,
wherein the second dummy die further includes:
a fifth bonding insulating film on the eighth surface of the fourth substrate; and
a second metal pattern in the fifth bonding insulating film,
wherein the second metal pattern includes a pattern that extends from a second corner region of the second dummy die across a central portion of the second dummy die in the plan view.

7. The semiconductor package of claim 6, further comprising:
a third dummy die on the second dummy die,
wherein the third dummy die includes:
a fifth substrate that includes a ninth surface that faces the eighth surface of the fourth substrate and a tenth surface that is opposite to the ninth surface in the first direction; and
a sixth bonding insulating film on the ninth surface of the fifth substrate,
wherein the sixth bonding insulating film is in contact with the fifth bonding insulating film.

8. The semiconductor package of claim 1, further comprising:
a plurality of second core dies between the first core die and the first dummy die,
wherein each of the plurality of second core dies includes:
a fourth substrate that includes a seventh surface and an eighth surface that are opposite to each other in the first direction;
a fourth bonding insulating film on the seventh surface of the fourth substrate;
a fifth bonding insulating film on the eighth surface of the fourth substrate;
a third bonding pad that extends in the fourth bonding insulating film in the first direction; and
a fourth bonding pad that extends in the fifth bonding insulating film in the first direction.

9. The semiconductor package of claim 8,
wherein the first core die further includes:
a sixth bonding insulating film on the fourth surface of the second substrate; and
a fifth bonding pad that extends in the sixth bonding insulating film in the first direction,
wherein the sixth bonding insulating film is in contact with the fourth bonding insulating film of a lowest second core die among the plurality of second core dies, and
wherein the fifth bonding pad is in contact with the third bonding pad of the lowest second core die among the plurality of second core dies.

10. The semiconductor package of claim 8,
wherein the first dummy die further includes:
a seventh bonding insulating film on the fifth surface of the third substrate; and
a sixth bonding pad that extends in the seventh bonding insulating film in the first direction,
wherein the seventh bonding insulating film is in contact with the fifth bonding insulating film of an uppermost second core die among the plurality of second core dies, and
the sixth bonding pad is in contact with the fourth bonding pad of the uppermost second core die among the plurality of second core dies.

11. A semiconductor package comprising:
a buffer die;
a first core die on the buffer die; and
a first dummy die on the first core die,
wherein the buffer die includes:
a first substrate that includes a first surface and a second surface that are opposite to each other in a first direction;
a first bonding insulating film that includes a third surface that faces the second surface of the first substrate and a fourth surface that is opposite to the third surface in the first direction; and
a first bonding pad that is exposed from the fourth surface,
wherein the first core die includes:
a second substrate that includes a fifth surface that faces the second surface of the first substrate and a sixth surface that is opposite to the fifth surface in the first direction;
a second bonding insulating film that is in contact with the first bonding insulating film and includes a seventh surface that faces the fourth surface of the first bonding insulating film and an eighth surface that is opposite to the seventh surface in the first direction; and
a second bonding pad that is exposed from the seventh surface and is in contact with to the first bonding pad,
wherein the first dummy die includes:
a third substrate that includes a ninth surface that faces the sixth surface of the second substrate and a tenth surface that is opposite to the ninth surface in the first direction;
a third bonding insulating film on the tenth surface of the third substrate; and
a first metal pattern in the third bonding insulating film,
wherein the first dummy die includes a first edge and a second edge that are opposite to each other in a second direction that intersects the first direction,
wherein the first edge extends from a first end to a second end in a third direction that intersects the first direction and the second direction,
wherein the second edge extends from a third end to a fourth end in the third direction,
wherein the first end and the third end are spaced apart from each other in the second direction,
wherein the second end and the fourth end are spaced apart from each other in the second direction,
wherein at least a part of the first metal pattern extends from adjacent the first end toward the fourth end in a plan view,
wherein the first direction is perpendicular to the first surface and/or the second surface of the buffer die, and
wherein the second direction and the third direction are parallel with the first surface and/or the second surface of the buffer die.

12. The semiconductor package of claim 11,
wherein at least a part of the first metal pattern extends from adjacent the second end toward the third end in the plan view.

13. The semiconductor package of claim 12,
wherein the first dummy die further includes a third edge and a fourth edge that are opposite to each other in the third direction,
wherein the third edge extends from the first end to the third end in the second direction,
wherein the fourth edge extends from the second end to the fourth end in the second direction,
wherein at least a part of the first metal pattern extends between the third edge and the fourth edge across a central portion of the first dummy die in the plan view, and
wherein at least a part of the first metal pattern extends between the first edge and the second edge across the central portion of the first dummy die in the plan view.

14. The semiconductor package of claim 11,
wherein the fourth surface of the first bonding insulating film includes a first region and a second region that extends around the first region in the plan view,
wherein the first core die and the first dummy die are stacked on the first region of the first bonding insulating film, and
wherein a plurality of connecting pads is disposed in the second region of the first bonding insulating film.

15. The semiconductor package of claim 11,
wherein the first dummy die further includes a fourth bonding insulating film between the third substrate and the third bonding insulating film,
wherein at least a part of the fourth bonding insulating film is in contact with the third bonding insulating film, and
wherein at least a part of the fourth bonding insulating film is in contact with the first metal pattern.

16. The semiconductor package of claim 11, further comprising:
a second dummy die on the first dummy die,
wherein the second dummy die includes:
a fourth substrate that includes an eleventh surface that faces the tenth surface of the third substrate and a twelfth surface that is opposite to the eleventh surface in the first direction;
a fourth bonding insulating film on the eleventh surface of the fourth substrate;
a fifth bonding insulating film on the twelfth surface of the fourth substrate; and
a second metal pattern in the fifth bonding insulating film,
wherein at least a part of the second metal pattern is in a central portion of the second dummy die in the plan view.

17. The semiconductor package of claim 16,
wherein the fourth bonding insulating film is in contact with the third bonding insulating film.

18. A method for manufacturing a semiconductor package, the method comprising:
providing a buffer die that includes a first substrate that has a first surface and a second surface opposite to each other in a first direction, a first bonding insulating film on the second surface of the first substrate, and a first bonding pad that extends in the first bonding insulating film in the first direction;
providing a core die that includes a second substrate that has a third surface and a fourth surface opposite to each other in the first direction, a second bonding insulating film on the third surface of the second substrate, and a second bonding pad that extends in the second bonding insulating film in the first direction;
providing a first dummy die that includes a third substrate that has a fifth surface and a sixth surface opposite to each other in the first direction, a third bonding insulating film on the sixth surface of the third substrate, and a first metal pattern in the third bonding insulating film, wherein the first metal pattern includes a first pattern that extends from a first corner region of the first dummy die across a central portion of the first dummy die in a plan view;
stacking the core die and the first dummy die in order on the buffer die;
applying a pressure to the core die and the first dummy die on the buffer die to bond the first bonding insulating film and the second bonding insulating film to each other; and
applying a heat to the core die and the first dummy die on the buffer die to bond the first bonding pad and the second bonding pad to each other,
wherein the first direction is perpendicular to the first surface and/or the second surface of the buffer die.

19. The method for manufacturing the semiconductor package of claim 18,
wherein the first metal pattern further includes a second pattern that extends from a second corner region of the first dummy die across the central portion of the first dummy die in the plan view,
wherein the first corner region and the second corner region are spaced from each other in a second direction that intersects the first direction, and
wherein the second direction is parallel with the first surface and/or the second surface of the buffer die.

20. The method for manufacturing the semiconductor package of claim 18, further comprising:
providing a second dummy die that includes a fourth substrate that has a seventh surface and an eighth surface opposite to each other in the first direction, a fourth bonding insulating film on the seventh surface of the fourth substrate, a fifth bonding insulating film on the eighth surface of the fourth substrate, and a second metal pattern in the fifth bonding insulating film;
stacking the second dummy die on the first dummy die; and
applying a pressure to the core die, the first dummy die, and the second dummy die on the buffer die to bond the third bonding insulating film and the fourth bonding insulating film to each other.
